(19) United States
(12) Patent Application Publication
(10) Pub. No.: US 2020/0313014 A1
(43) Pub. Date: Oct. 1, 2020

(54) PREPARATION METHOD OF SOLAR CELL BACKSHEET FILM WITH HIGH REFLECTIVITY

(71) Applicant: ZHONGTIAN PHOTOVOLTAIC MATERIALS Co.,LTD., Nantong (CN)

(72) Inventors: YAN-NING WANG, Nantong (CN); QIANG WANG, Nantong (CN); KUN CHEN, Nantong (CN); XIANG-AN LIU, Nantong (CN); JIE LIAO, Nantong (CN)

(21) Appl. No.: 16/832,043

(22) Filed: Mar. 27, 2020

Related U.S. Application Data
(63) Continuation-in-part of application No. PCT/CN2017/104028, filed on Sep. 28, 2017.

(30) Foreign Application Priority Data
Sep. 27, 2017 (CN) 201710887323.0

(51) Int. Cl. H01L 31/049; H01L 31/18

(52) U.S. Cl. CPC H01L 31/049; H01L 31/1876

(57) ABSTRACT

The disclosure discloses a method for preparing a high-reflection solar cell backsheet film, which uses a twin-screw extruder to prepare a masterbatch of an adhesive layer, a masterbatch of a barrier layer, and a masterbatch of a high-reflection layer, and then uses four single-screw extruders to melt the three masterbatches at 250° C. and extrude through a lip film of a casting head. A non-woven fabric is added as a base layer between the two barrier layers, so that the two barrier layers are extruded through the lip film and integrally formed on surfaces of the non-woven fabric. After being cooled to room temperature by a cooling roller, a highly reflective solar cell backsheet is obtained.

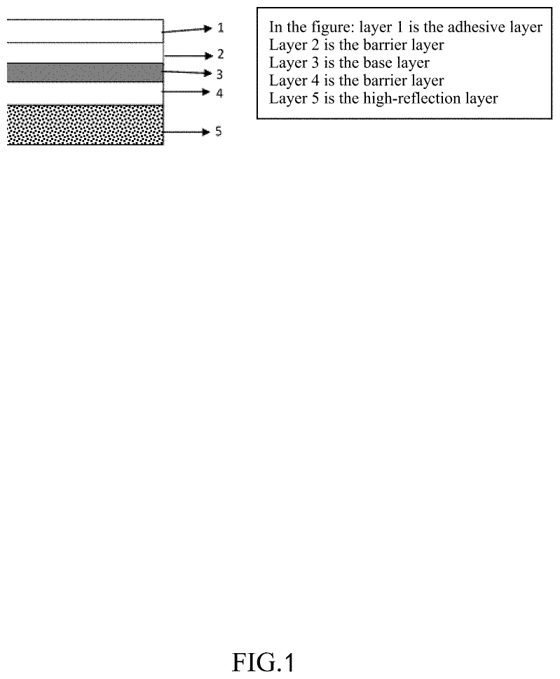

### TECHNICAL FIELD

The disclosure belongs to the field of solar cell backsheets, and in particular relates to a method for preparing a solar cell backsheet film with high reflectivity.

### BACKGROUND TECHNIQUE

Solar photovoltaic modules are mainly composed of photovoltaic tempered glass, an upper EVA film, crystalline silicon cells, a lower EVA film, and a backsheet. A conventional photovoltaic backsheet generally is a five-layer structure, including from top to bottom, an inner layer of the backsheet, an adhesive layer, a PET layer, an adhesive layer, and an outermost protective layer. According to the different materials used in each layer of the backsheet, the backsheet can be divided into TPT, KPK, KPF, KPE, etc.

The photovoltaic backsheet not only has the function of protecting components, but also can effectively improve the power generation efficiency. According to research, for every 8% increase in backsheet reflectivity, a 250 W module's power generation can increase by 1-2 W. At the same time, after the reflectance is increased, the module temperature can be effectively reduced, and the backsheet's resistance to ultraviolet light is increased thereby reducing the speed of yellowing and brittleness, effectively reducing the aging speed of the backsheet and prolonging the service life. The inner material of the backsheet plays an important role in improving the reflectivity. At present, conventional inner materials of the backsheet include K film, T film, fluorine coating, and films independently developed by the backsheet manufacturers. The reflectivity may be poor and may not achieve the effect of increasing component power.

Chinese Patent No. CN103022192A disclosed high-reflection solar backsheets have been developed, such as a high-reflectivity solar cell backsheet film and its preparation method; however, the production processes may be complicated and require bonding with an adhesive. On the one hand, the cost may be increased, because the bonding of the adhesive has specific requirements on temperature, which prolongs the production cycle.

### SUMMARY

A method for preparing a solar cell backsheet film comprising:

Block a. Polyolefin resin, white POE masterbatch, mixed filler, triethyl phosphate, antioxidant 1010, polycarbodiimide UN-03, and 2-(4,6-diphenyl-1,3,5-Triazin-2-yl-)-5-hexyloxyphenol are mixed and granule-extruded through a twin-screw extruder. The temperature of the twin-screw extruder in zone I is controlled at 65° C., the temperature in zone II at 165° C., the temperature in zone III at 185° C., the temperature in zone IV at 195° C., the temperature in zone V at 210° C., and the head temperature at 200° C. The material stays in the twin-screw for 3.5 minutes to obtain the masterbatch of the adhesive layer;

Block b. PET particles with a molecular weight of 47000 are dried in a vacuum drum at 80° C. for 3 hours. Triethyl phosphate, pentaerythritol tetrakis (bis-T-butylhydroxyhydrocinnamic acid) ester, antioxidant 1010, polycarbodiimide UN-03, 2-(4,6-diphenyl-1,3,5-triazin-2-yl-)-5-hexyloxyphenol, TiO2, SiO2, ethylene-methyl acrylate copolymer, ethylene-vinyl acetate copolymer, talc, sodium benzoate, and ethylene-(meth) acrylic acid copolymer are mixed and granule-extruded through a twin-screw extruder. The temperature of zone I in the twin-screw extruder is 120° C., the temperature in zone II is 170° C., the temperature in zone III is 220° C., the temperature in zone IV is 245° C., the temperature in zone V is 240° C., and the head temperature is 220° C. The material stays in the twin-screw for 3.5 minutes to obtain the masterbatch of the barrier layer;

Block c. PC resin, titanium dioxide, triethyl phosphate, antioxidant 1010, polycarbodiimide UN-03, and 2-(4,6-diphenyl-1,3,5-triazin-2-yl-)-5-hexyloxyphenol are mixed and granule-extruded through a twin-screw extruder. In the twin-screw extruder, the temperature in zone I is 120° C., the temperature in zone II is 170° C., the temperature in zone III is 230° C., the temperature in zone IV is 245° C., the temperature in zone V is 240° C., and the head temperature is 220° C. The material stays in the twin-screw for 3.5 min to obtain the masterbatch of the high-reflection layer;

Block d. The prepared masterbatch of the adhesive layer, masterbatch of the barrier layer, and masterbatch of the high-reflection layer are separately put into four single-screw extruders. The masterbatch of the adhesion layer, the masterbatch of the barrier layer, the master batch of the barrier layer, and the masterbatch of the high-reflection layer are separately put in the four single-screw extruders, melted at 250° C., and extruded through the lip film of the casting head. A non-woven fabric is added as a base layer between the two barrier layers, so that the two barrier layers are extruded through the lip film and integrally formed on surfaces of the non-woven fabric. After being cooled to room temperature by a cooling roller, a highly reflective solar cell backsheet is obtained.

The mixed filler in Block a is composed of titanium dioxide and talc or barium sulfate or mica in a ratio of 5:1.

The polyolefin resin is a PP resin, a PE resin or a cycloolefin polymer.

### BRIEF DESCRIPTION OF DRAWINGS

The FIGURE is a schematic diagram of an embodiment of a backsheet film for a high-reflection solar cell.

### DETAILED DESCRIPTION

In the following, embodiments of the present disclosure will be clearly and completely described in combination with the specific contents of the present disclosure.

### Embodiment 1

A method for preparing a backsheet film for a high-reflection solar cell disclosed in the present disclosure includes the following steps:

70 parts of PP resin, 20 parts of white POE masterbatch, 5 parts of titanium dioxide and 6 parts of talc mixed filler (the ratio of titanium dioxide to talc is 5:1), 0.5 parts of triethyl phosphate, 0.5 parts of antioxidant 1010, 2 parts of polycarbodiimide UN-03, and 2 parts of 2-(4,6-diphenyl-1,3,5-triazin-2-yl-)-5-hexyloxyphenol are mixed and granule-extruded the mixture through a twin-screw extruder. In the twin-screw extruder, the temperature of zone I is 65° C., the temperature of zone II is 165° C., the temperature of zone III is 185° C., the temperature of zone IV is 195° C., the temperature of zone V is 210° C., and the head temperature is 200° C. The material stays in the twin-screw for 3.5 min to obtain the masterbatch of the adhesive layer.

50 parts of PET particles with a molecular weight of 47000 are dried in a vacuum drum at 80° C. for 3 hours, and 0.1 part of triethyl phosphate, 0.1 part of pentaerythritol tetrakis (double-T-butyl hydroxyhydrocinnamic acid) ester, 0.1 part antioxidant 1010, 2 parts of polycarbodiimide UN-03, 2 parts of 2-(4,6-diphenyl-1,3,5-triazine 2-yl-)-5-hexyloxyphenol, 2 parts of TiO2, 1 part of SiO2, 2 parts of ethylene-methyl acrylate copolymer, 3 parts of ethylene-vinyl acetate copolymer, 0.1 part of talc, 0.1 part of Sodium benzoate, and 0.3 parts of ethylene-(meth) acrylic acid copolymer are added and mixed. The mixture is granule-extruded through a twin-screw extruder. In the twin-screw extruder, the temperature in zone I is 120° C., the temperature in zone II is 170° C., the temperature in zone III is 220° C., the temperature in zone IV is 245° C., the temperature in zone V is 240° C., and the head temperature is 220° C. The material stays in the twin-screw for 3.5 min to obtain the masterbatch of the barrier layer.

70 parts of PC resin, 25 parts of titanium dioxide, 0.5 parts of triethyl phosphate, 0.5 parts of antioxidant 1010, 2 parts of polycarbodiimide UN-03, 2 parts of 2-(4,6-diphenyl-1,3,5-triazin-2-yl-)-5-hexyloxyphenol are mixed and granule-extruded through a twin-screw extruder. In the twin-screw extruder, the temperature in zone I is 120° C., the temperature in zone II is 170° C., the temperature in zone III is 230° C., the temperature in zone IV is 245° C., the temperature in zone V is 240° C., and the head temperature is 220° C. The material stays in the twin-screw for 3.5 min to obtain the masterbatch of the high-reflection layer.

The prepared masterbatch of the adhesive layer, masterbatch of the barrier layer, and masterbatch of the high-reflection layer are separately put into four single-screw extruders. The masterbatch of the adhesion layer, the masterbatch of the barrier layer, the master batch of the barrier layer, and the masterbatch of the high-reflection layer are separately put in the four single-screw extruders, melted at 250° C., and extruded through the lip film of the casting head. A non-woven fabric is added as a base layer between the two barrier layers, so that the two barrier layers are extruded through the lip film and integrally formed on surfaces of the non-woven fabric. After being cooled to room temperature by a cooling roller, a highly reflective solar cell backsheet is obtained.

### Embodiment 2

65 parts of PE resin, 30 parts of white POE masterbatch, 5 parts of titanium dioxide and 6 parts of talc mixed filler (the ratio of titanium dioxide to talc is 5:1), 0.5 parts of triethyl phosphate, 0.5 parts of antioxidant 1010, 2 parts of polycarbodiimide UN-03, and 2 parts of 2-(4,6-diphenyl-1,3,5-triazin-2-yl-)-5-hexyloxyphenol are mixed and granule-extruded through a twin-screw extruder. In the twin-screw extruder, the temperature in zone I is 65° C., the temperature in zone II is 165° C., the temperature in zone III is 185° C., the temperature in zone IV is 195° C., the temperature in zone V is 210° C., and the head temperature is 200° C. The material stays in the twin-screw for 3.5 min to obtain the masterbatch of the adhesive layer.

70 parts of PET particles with a molecular weight of 47000 are dried at 80° C. in a vacuum drum for 3 hours, and 0.1 part of triethyl phosphate, 0.1 part of pentaerythritol tetrakis (bis-T-butylhydroxyhydrocinnamic acid) ester, 0.1 part of antioxidant 1010, 2 parts of polycarbodiimide UN-03, 2 parts of 2-(4,6-diphenyl-1,3,5-triazin-2-yl-)-5-hexyloxyphenol, 2 parts of TiO2, 1 part of SiO2, 2 parts of ethylene-methyl acrylate copolymer, 3 parts of ethylene-vinyl acetate copolymer, 0.1 part of talc, 0.1 part of sodium benzoate, and 0.3 parts of ethylene-(meth) acrylic acid copolymer are added and mixed. The mixture is granule-extruded through a twin-screw extruder. In the twin-screw extruder, the temperature in zone I is 120° C., the temperature in zone II is 170° C., the temperature in zone III is 220° C., the temperature in zone IV is 245° C., the temperature in zone V is 240° C., and the head temperature is 220° C. The material stays in the twin-screw for 3.5 minutes to obtain the masterbatch of the barrier layer.

65 parts of PC resin, 30 parts of titanium dioxide, 0.5 parts of triethyl phosphate, 0.5 parts of antioxidant 1010, 2 parts of polycarbodiimide UN-03, and 2 parts of 2-(4,6-diphenyl-1,3,5-triazin-2-yl-)-5-hexyloxyphenol are mixed and granule-extruded through a twin-screw extruder. In the twin-screw extruder, the temperature in zone I is 120° C., the temperature in zone II is 170° C., the temperature in zone III is 230° C., the temperature in zone IV is 245° C., the temperature in zone V is 240° C., and the head temperature is 220° C. The material stays in the twin-screw for 3.5 min to obtain the masterbatch of the high-reflection layer.

The prepared masterbatch of the adhesive layer, masterbatch of the barrier layer, and masterbatch of the high-reflection layer are separately put into four single-screw extruders. The masterbatch of the adhesion layer, the masterbatch of the barrier layer, the master batch of the barrier layer, and the masterbatch of the high-reflection layer are separately put in the four single-screw extruders, melted at 250° C., and extruded through the lip film of the casting head. A non-woven fabric is added as a base layer between the two barrier layers, so that the two barrier layers are extruded through the lip film and integrally formed on surfaces of the non-woven fabric. After being cooled to room temperature by a cooling roller, a highly reflective solar cell backsheet is obtained.

The performance test method is as follows:

Humidity and heat aging resistance: Double 85 aging resistance test, tested under the environmental conditions of 85° C. and 85% humidity;

UV aging test: Q8/UV accelerated testing machine for testing;

Water vapor transmission rate test: infrared sensor method, conditions: 38° C., 100% relative humidity.

Reflectivity test: Reflectance tester wavelength range: 380-1100 nm

| Test item | Backsheet | Embodiment 1 | Embodiment 2 |
|---|---|---|---|
| Humidity and | 3000 | 3000 | 3000 |
| heat aging (h) | | | |
| Heat shrinkage (%) | 0.37 | 0.25 | 0.20 |
| Water vapor | 1.1 | 0.75 | 0.75 |
| transmission | | | |
| (g/(m²*d)) | | | |
| Reflectivity (%) | 84 | 96 | 98 |

The present disclosure is to provide a method for preparing a high-reflection solar cell backsheet film, which is formed by a single extrusion and casting step, which saves production costs and shortens the production cycle. The prepared backsheet film has better adhesiveness, good barrier properties, electrical insulation and aging resistance, and high reflectivity.

The method as disclosed in the present disclosure has the following features:

The prepared backsheet film has a multi-layer structure, which not only satisfies adhesion with the outer fluorine film, but also improves the reflectivity of the backsheet, which can reach about 99%, and the formed solar module can have a gain reaching above 1.5 W. The non-woven fabric is used as the middle base layer in the multilayer backsheet film. The strength of the backsheet can be improved under the premise of ensuring the insulation of the backsheet. The use of two barrier layers can improve the overall water blocking performance. The adhesive layer makes the backsheet film and fluorine film have better adhesion performance;

For the connection between the layers, a single extrusion casting step is used, which not only saves production costs, but also shortens the production cycle. Under the premise of ensuring the performance of the backsheet film, the processing cycle is improved. At the same time, in the traditional composite backsheet, the adhesive layer is usually a two-component polyurethane glue. During the solvent volatilization process, the long-term performance of the backsheet will be attenuated, and the cell will be corroded. The backsheet film produced by the casting method can effectively reduce harm.

The above describes one embodiment of the present disclosure in detail, but the contents are only a preferred embodiment of the present disclosure, and cannot be considered to limit the scope of implementation of the present disclosure. All equal changes and improvements made in accordance with the scope of the present disclosure's application are covered by the scope of the disclosure's patent.

What is claimed is:

1. A method for preparing a solar cell backsheet film comprising:
preparing a masterbatch of an adhesive layer;
preparing a masterbatch of a first barrier layer and a second barrier layer;
preparing a masterbatch of a high-reflection layer;
extruding the masterbatch of the adhesion layer, the masterbatch of the first barrier layer, the master batch of the second barrier layer, and the masterbatch of the high-reflection layer through four single-screw extruders; and
cooling the extruded masterbatch of the adhesion layer, the masterbatch of the first barrier layer, the master batch of the second barrier layer, and the masterbatch of the high-reflection layer to room temperature to obtain the solar cell backsheet film.

2. The method of claim 1 further comprising:
providing a non-woven fabric as a base layer; and
integrally forming the first barrier layer and the second barrier layer on surfaces of the non-woven fabric.

3. The method of claim 1, wherein:
the masterbatch of the adhesive layer comprises polyolefin resin, white POE masterbatch, mixed filler, triethyl phosphate, antioxidant 1010, polycarbodiimide UN-03, and 2-(4,6-diphenyl-1,3,5-Triazin-2-yl-)-5-hexyloxyphenol.

4. The method of claim 3, wherein:
the polyolefin resin is a PP resin, a PE resin, or a cycloolefin polymer; and
the mixed filler is composed of titanium dioxide and talc, barium sulfate, or mica in a ratio of 5:1.

5. The method of claim 4, wherein a method of preparing the masterbatch of the adhesive layer comprises:
preparing a mixture of 70 parts of PP resin, 20 parts of white POE masterbatch, 5 parts of titanium dioxide and talc mixed filler, 0.5 parts of triethyl phosphate, 0.5 parts of antioxidant 1010, 2 parts of polycarbodiimide UN-03, and 2 parts of 2-(4,6-diphenyl-1,3,5-triazin-2-yl-)-5-hexyloxyphenol; and
granule-extruding the mixture through a twin-screw extruder.

6. The method of claim 5, wherein a method of granule-extruding the mixture comprises:
controlling temperatures of zone 1, zone II, zone III, and a head temperature of the twin-screw extruder, wherein a temperature of zone I is 65° C., a temperature of zone II is 165° C., a temperature of zone III is 185° C., a temperature of zone IV is 195° C., a temperature of zone V is 210° C., and the head temperature is 200° C.; and
maintaining the mixture in the twin-screw for 3.5 minutes.

7. The method of claim 1, wherein:
the masterbatch of the first and second barrier layers comprises PET particles, triethyl phosphate, pentaerythritol tetrakis (double-T-butyl hydroxyhydrocinnamic acid) ester, antioxidant 1010, polycarbodiimide UN-03, 2-(4,6-diphenyl-1,3,5-triazine 2-yl-)-5-hexyloxyphenol, TiO2, SiO2, ethylene-methyl acrylate copolymer, ethylene-vinyl acetate copolymer, talc, sodium benzoate, and ethylene-(meth) acrylic acid copolymer.

8. The method of claim 7, wherein a method of preparing the masterbatch of the first and second barrier layers comprises preparing a mixture by:
drying 50 parts of PET particles with a molecular weight of 47000 in a vacuum drum at 80° C. for 3 hours;
adding and mixing 0.1 part of triethyl phosphate, 0.1 part of pentaerythritol tetrakis (double-T-butyl hydroxyhydrocinnamic acid) ester, 0.1 part antioxidant 1010, 2 parts of polycarbodiimide UN-03, 2 parts of 2-(4,6-diphenyl-1,3,5-triazine 2-yl-)-5-hexyloxyphenol, 2 parts of TiO2, 1 part of SiO2, 2 parts of ethylene-methyl acrylate copolymer, 3 parts of ethylene-vinyl acetate copolymer, 0.1 part of talc, 0.1 part of sodium benzoate, and 0.3 parts of ethylene-(meth) acrylic acid copolymer; and
granule-extruding the mixture through a twin-screw extruder.

9. The method of claim 8, wherein:
in the twin-screw extruder, a temperature in zone I is 120° C., a temperature in zone II is 170° C., a temperature in zone III is 220° C., a temperature in zone IV is 245° C., a temperature in zone V is 240° C., and a head temperature is 220° C.; and
the mixture stays in the twin-screw for 3.5 min.

10. The method of claim 1, wherein:
the masterbatch of the high-reflection layer comprises PC resin, titanium dioxide, triethyl phosphate, antioxidant 1010, polycarbodiimide UN-03, and 2-(4,6-diphenyl-1,3,5-triazin-2-yl-)-5-hexyloxyphenol.

11. The method of claim 10, wherein a method of preparing the masterbatch of the high-reflection layer comprises:
preparing a mixture of 70 parts of PC resin, 25 parts of titanium dioxide, 0.5 parts of triethyl phosphate, 0.5 parts of antioxidant 1010, 2 parts of polycarbodiimide UN-03, and 2 parts of 2-(4,6-diphenyl-1,3,5-triazin-2-yl-)-5-hexyloxyphenol; and
granule-extruding the mixture through a twin-screw extruder.

12. The method of claim 11, wherein:
in the twin-screw extruder, a temperature in zone I is 120° C., a temperature in zone II is 170° C., a temperature in zone III is 230° C., a temperature in zone IV is 245° C., a temperature in zone V is 240° C., and a head temperature is 220° C.; and
the mixture stays in the twin-screw for 3.5 min.

13. The method of claim 4, wherein a method of preparing the masterbatch of the adhesive layer comprises:
preparing a mixture of 65 parts of PE resin, 30 parts of white POE masterbatch, 5 parts of titanium dioxide and talc mixed filler, 0.5 parts of triethyl phosphate, 0.5 parts of antioxidant 1010, 2 parts of polycarbodiimide UN-03, and 2 parts of 2-(4,6-diphenyl-1,3,5-triazin-2-yl-)-5-hexyloxyphenol; and
granule-extruding the mixture through a twin-screw extruder.

14. The method of claim 13, wherein:
in the twin-screw extruder, a temperature in zone I is 65° C., a temperature in zone II is 165° C., a temperature in zone III is 185° C., a temperature in zone IV is 195° C., a temperature in zone V is 210° C., and a head temperature is 200° C.; and
the mixture stays in the twin-screw for 3.5 min.

15. The method of claim 1, wherein a method of preparing the first and the second barrier layers comprises preparing a mixture by:
drying 70 parts of PET particles with a molecular weight of 47000 at 80° C. in a vacuum drum for 3 hours;
adding and mixing 0.1 part of triethyl phosphate, 0.1 part of pentaerythritol tetrakis (bis-T-butylhydroxyhydrocinnamic acid) ester, 0.1 part of antioxidant 1010, 2 parts of polycarbodiimide UN-03, 2 parts of 2-(4,6-diphenyl-1,3,5-triazin-2-yl-)-5-hexyloxyphenol, 2 parts of TiO2, 1 part of SiO2, 2 parts of ethylene-methyl acrylate copolymer, 3 parts of ethylene-vinyl acetate copolymer, 0.1 part of talc, 0.1 part of sodium benzoate, and 0.3 parts of ethylene-(meth) acrylic acid copolymer; and
granule-extruding the mixture through a twin-screw extruder.

16. The method of claim 15, wherein:
in the twin-screw extruder, a temperature in zone I is 120° C., a temperature in zone II is 170° C., a temperature in zone III is 220° C., a temperature in zone IV is 245° C., a temperature in zone V is 240° C., and a head temperature is 220° C.; and
the mixture stays in the twin-screw for 3.5 minutes.

17. The method of claim 1, wherein a method of preparing the masterbatch of the high-reflection layer comprises:
preparing a mixture of 65 parts of PC resin, 30 parts of titanium dioxide, 0.5 parts of triethyl phosphate, 0.5 parts of antioxidant 1010, 2 parts of polycarbodiimide UN-03, and 2 parts of 2-(4,6-diphenyl-1,3,5-triazin-2-yl-)-5-hexyloxyphenol; and
granule-extruding the mixture through a twin-screw extruder.

18. The method of claim 17, wherein:
in the twin-screw extruder, a temperature in zone I is 120° C., a temperature in zone II is 170° C., a temperature in zone III is 230° C., a temperature in zone IV is 245° C., a temperature in zone V is 240° C., and a head temperature is 220° C.; and
the mixture stays in the twin-screw for 3.5 min.

19. A high-reflection solar cell backsheet film comprising:
an adhesive layer comprising 70 parts of PP resin, 20 parts of white POE masterbatch, 5 parts of titanium dioxide and talc mixed filler, 0.5 parts of triethyl phosphate, 0.5 parts of antioxidant 1010, 2 parts of polycarbodiimide UN-03, and 2 parts of 2-(4,6-diphenyl-1,3,5-triazin-2-yl-)-5-hexyloxyphenol;
a first barrier layer and a second barrier layer each comprising 50 parts of PET particles with a molecular weight of 47000, 0.1 part of triethyl phosphate, 0.1 part of pentaerythritol tetrakis (double-T-butyl hydroxyhydrocinnamic acid) ester, 0.1 part antioxidant 1010, 2 parts of polycarbodiimide UN-03, 2 parts of 2-(4,6-diphenyl-1,3,5-triazine 2-yl-)-5-hexyloxyphenol, 2 parts of TiO2, 1 part of SiO2, 2 parts of ethylene-methyl acrylate copolymer, 3 parts of ethylene-vinyl acetate copolymer, 0.1 part of talc, 0.1 part of sodium benzoate, and 0.3 parts of ethylene-(meth) acrylic acid copolymer;
a base layer located between the first and second barrier layers; and
a high-reflection layer comprising 70 parts of PC resin, 25 parts of titanium dioxide, 0.5 parts of triethyl phosphate, 0.5 parts of antioxidant 1010, 2 parts of polycarbodiimide UN-03, and 2 parts of 2-(4,6-diphenyl-1,3,5-triazin-2-yl-)-5-hexyloxyphenol.

20. A high-reflection solar cell backsheet film comprising:
an adhesive layer comprising 65 parts of PE resin, 30 parts of white POE masterbatch, 5 parts of titanium dioxide and talc mixed filler, 0.5 parts of triethyl phosphate, 0.5 parts of antioxidant 1010, 2 parts of polycarbodiimide UN-03, and 2 parts of 2-(4,6-diphenyl-1,3,5-triazin-2-yl-)-5-hexyloxyphenol;
a first barrier layer and a second barrier layer each comprising 70 parts of PET particles with a molecular weight of 47000, 0.1 part of triethyl phosphate, 0.1 part of pentaerythritol tetrakis (bis-T-butylhydroxyhydrocinnamic acid) ester, 0.1 part of antioxidant 1010, 2 parts of polycarbodiimide UN-03, 2 parts of 2-(4,6-diphenyl-1,3,5-triazin-2-yl-)-5-hexyloxyphenol, 2 parts of TiO2, 1 part of SiO2, 2 parts of ethylene-methyl acrylate copolymer, 3 parts of ethylene-vinyl acetate copolymer, 0.1 part of talc, 0.1 part of sodium benzoate, and 0.3 parts of ethylene-(meth) acrylic acid copolymer;
a base layer located between the first and second barrier layers; and
a high-reflection layer comprising 65 parts of PC resin, 30 parts of titanium dioxide, 0.5 parts of triethyl phosphate, 0.5 parts of antioxidant 1010, 2 parts of polycarbodiimide UN-03, and 2 parts of 2-(4,6-diphenyl-1,3,5-triazin-2-yl-)-5-hexyloxyphenol.
